(19) United States
(12) Patent Application Publication
(10) Pub. No.: US 2010/0159122 A1
(43) Pub. Date: Jun. 24, 2010

(54) DEPOSITION FILM FORMING APPARATUS, DEPOSITION FILM FORMING METHOD AND ELECTROPHOTOGRAPHIC PHOTOSENSITIVE MEMBER MANUFACTURING METHOD

(75) Inventors: Kazuto Hosoi, Mishima-shi (JP); Kazuyoshi Akiyama, Mishima-shi (JP); Yukihiro Abe, Mishima-shi (JP); Motoya Yamada, Suntou-gun (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/627,125

(22) Filed: Nov. 30, 2009

(30) Foreign Application Priority Data
Dec. 19, 2008 (JP) 2008-324205

(51) Int. Cl. C23C 16/44; C23C 16/00

(52) U.S. Cl. 427/58; 118/715; 427/248.1

(57) ABSTRACT

The present invention provides a deposition film forming apparatus including a reaction container, an exhaust device and an exhaust gas flow path for causing a material gas to flow from the reaction container to the exhaust device, wherein the exhaust gas flow path includes a portion whose cross section expands with a step with respect to a direction in which the material gas flows and the deposition film forming apparatus further includes a cleaning gas flow device for causing the cleaning gas to directly flow into a region closer to the exhaust device side than the step of the exhaust gas flow path, a deposition film forming method using the deposition film forming apparatus and a method of manufacturing an electrophotographic photosensitive member using the deposition film forming method.

### BACKGROUND OF THE INVENTION

1. Field of the Invention

The present invention relates to a deposition film forming apparatus, a deposition film forming method and an electrophotographic photosensitive member manufacturing method.

2. Related Background Art

Conventionally, a kind of deposition film forming methods is known which decomposes a material gas using a method such as RF glow discharge, causes the material gas to be vapor-deposited on a substrate and forms a deposition film. Hereinafter, this deposition film forming method will also be referred to as a “vacuum deposition method”. The vacuum deposition method is used, for example, to manufacture an electrophotographic photosensitive member created by forming an amorphous silicon deposition film on an aluminum substrate (conductive substrate).

Furthermore, the vacuum deposition method generally uses a technique of exhausting a material gas (also including a decomposed material gas) remaining in a reaction container through an exhaust gas flow path communicating with an exhaust device.

According to the vacuum deposition method, the whole material gas introduced into a reaction container is not necessarily decomposed in the reaction container, evaporated onto a substrate and formed as a deposition film. According to the vacuum deposition method, a by-product is accumulated in the exhaust gas flow path or the exhaust device as the deposition film is formed. When a large volume of by-product is accumulated in the exhaust gas flow path or the exhaust device, an enormous amount of time is required for processing of removing the by-product in the exhaust gas flow path or the exhaust device. Furthermore, when a large volume of by-product is accumulated in the exhaust gas flow path, the exhaust gas flow path may be blocked while the deposition film is being formed. Moreover, when a large volume of by-product is accumulated in the exhaust device, the load on the exhaust device increases, causing the exhaust performance to decrease.

With regard to the removal of a by-product produced simultaneously with the formation of a deposition film, Japanese Patent Application Laid-Open No. 2002-343785 discloses a technique of causing a treatment to flow into the exhaust gas flow path to rend harmless the residue produced when the deposition film is formed and processing the residue through a plasma processing unit set in the exhaust gas flow path.

According to the aforementioned prior art, it is possible to reduce the by-product accumulated in the exhaust gas flow path during the formation of the deposition film.

However, it has been revealed that when a cleaning gas is introduced into part of the exhaust gas flow path during the formation of the deposition film, the cleaning gas may be back-diffused toward the reaction container side depending on deposition film formation conditions, affecting characteristics of the deposition film.

Especially when a radicalized cleaning gas is introduced to improve the cleaning efficiency, there is a problem that a mean free path increases compared to a non-radicalized cleaning gas and the above described back diffusion distance increases making it more likely to affect the characteristics of the deposition film in particular.

For the vacuum deposition method, it is very important that impurity components other than the material gas not be introduced into the reaction container. When the cleaning gas is back-diffused toward the reaction container side, a component of the cleaning gas may be mixed into the deposition film formed as an impurity, leading to deterioration of the quality of the deposition film.

### SUMMARY OF THE INVENTION

It is an object of the present invention to provide a deposition film forming apparatus and a deposition film forming method that suppresses influences of back diffusion of a cleaning gas toward a reaction container side on characteristics of a deposition film.

The present invention is a deposition film forming apparatus including a reaction container that can be vacuum-sealed for decomposing a material gas, causing the material gas to be vapor-deposited on a substrate to form a deposition film, an exhaust device for exhausting the gas from the reaction container and an exhaust gas flow path for communicating between the reaction container and the exhaust device and causing the material gas to flow from the reaction container to the exhaust device, wherein the exhaust gas flow path includes a portion whose cross section expands with a step with respect to a direction in which the material gas flows, and the deposition film forming apparatus further includes a cleaning gas flow device for causing the cleaning gas to directly flow into a region closer to the exhaust device side than the step of the exhaust gas flow path.

Furthermore, the present invention is a method of forming a deposition film on a substrate using the above described deposition film forming apparatus, decomposing a material gas in the reaction container, causing the material gas to be vapor-deposited on a substrate to form a deposition film and causing a cleaning gas to directly flow into a region closer to the exhaust device side than the above described step of the above described exhaust gas flow path.

The present invention can provide a deposition film forming apparatus and a deposition film forming method that suppresses influences of back diffusion of a cleaning gas toward the reaction container side on characteristics of the deposition film.

Further features of the present invention will become apparent from the following description of examples with reference to the attached drawings.

### BRIEF DESCRIPTION OF THE DRAWINGS

FIG. 1 is a schematic diagram illustrating an example of a deposition film forming apparatus.

FIG. 2 is a schematic diagram illustrating an example of an exhaust gas flow path.

FIGS. 3A, 3B, 3C and 3D are schematic diagrams illustrating examples of the exhaust gas flow path.

FIG. 4 is a schematic diagram of the deposition film forming apparatus used in comparative example 1.

FIG. 5 is a schematic diagram of the deposition film forming apparatus used in comparative example 2.

FIG. 6 is a schematic view illustrating an example of a layer configuration of an electrophotographic photosensitive member.

### DESCRIPTION OF THE EMBODIMENTS

As a result of an elaborate investigation, the present inventor et al. discovered that the configuration of an exhaust gas flow path for causing a cleaning gas to flow is important to suppress back diffusion of the cleaning gas toward the reaction container side. To be more specific, the present inventor et al. came up with the present invention by discovering that the back diffusion of the cleaning gas toward the reaction container side can be suppressed by providing a portion whose cross section expands with a step with respect to a direction in which a material gas flows in the exhaust gas flow path and causing the cleaning gas to directly flow into a region closer to the exhaust device side than the step of the exhaust gas flow path.

Hereinafter, examples of the present invention will be described in detail with reference to the accompanying drawings.

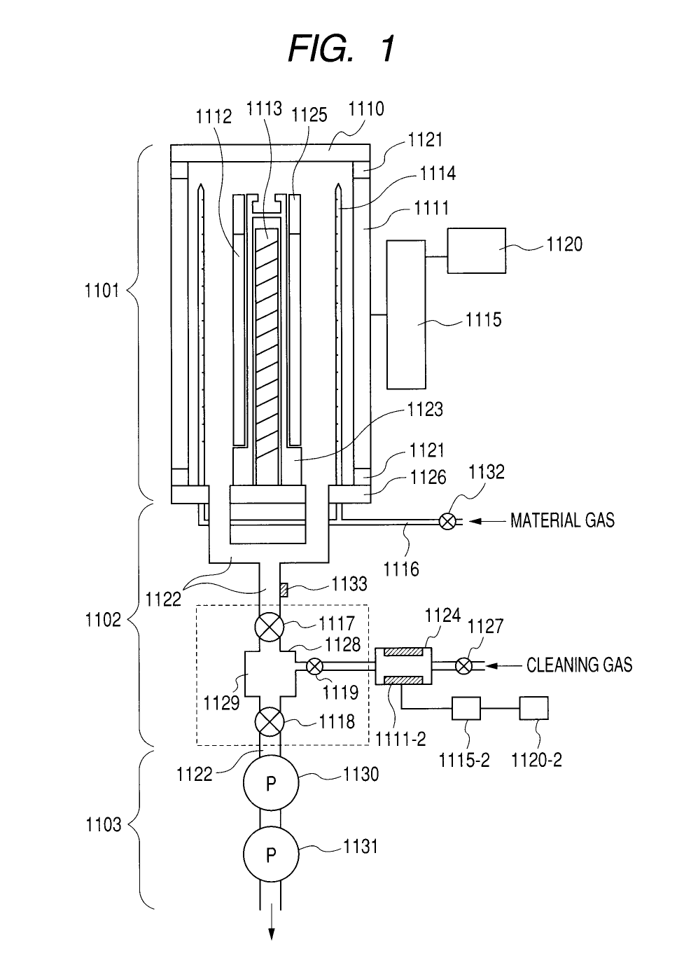

FIG. 1 is a schematic diagram illustrating an example of a deposition film forming apparatus (vacuum deposition apparatus) according to the present invention.

The deposition film forming apparatus includes a cylindrical reaction container 1101 that can be vacuum-sealed, an exhaust device 1103 for exhausting a gas from the reaction container 1101 and an exhaust gas flow path 1102 that communicates between the reaction container 1101 and the exhaust device 1103.

The reaction container 1101 includes a high frequency electrode 1111 insulated from a top cover 1110 and a bottom plate 1126 by an insulating member 1121. A grounded cylindrical substrate 1112, a heater 1113 for heating the cylindrical substrate and a material gas lead-in pipe 1114 are placed in the reaction container 1101. Furthermore, a high frequency power supply 1120 is connected to the reaction container 1101 via a high frequency matching box 1115.

The cylindrical substrate 1112 is placed on a substrate holder 1123 and a cap holder 1125 is further placed on top of the cylindrical substrate 1112. The substrate holder 1123 and the cap holder 1125 are made of a conductive member and the cylindrical substrate 1112 made of a conductive member is grounded via the substrate holder 1123.

The exhaust device 1103 has an oil rotation pump 1131 and a mechanical booster pump 1130, and exhausts the gas from the reaction container 1101 to reduce the pressure in the reaction container 1101.

The exhaust gas flow path 1102 of the present invention includes an exhaust pipe 1122, and the exhaust pipe 1122 includes a portion 1129 whose cross section expands with a step 1128 exists. Furthermore, the deposition film forming apparatus in FIG. 1 has a cleaning gas flow device 1124 for causing the cleaning gas to directly flow into a region closer to the exhaust device 1103 side than the step 1128. “Causing the cleaning gas to directly flow” means that when the cleaning gas is introduced from the cleaning gas flow device into the region closer to the exhaust device 1103 side than the step 1128, the cleaning gas is directly introduced instead of introducing the cleaning gas via the reaction container 1101. When a radicalized cleaning gas is used as the cleaning gas, the cleaning gas can be radicalized by using the cleaning gas flow device as a plasma generation unit. The deposition film forming apparatus in FIG. 1 is a deposition film forming apparatus that can radicalize the cleaning gas and the cleaning gas flow device 1124, which is also a plasma generation unit, includes a high frequency electrode 1111-2. Furthermore, the cleaning gas flow device 1124 is connected to a high frequency power supply 1120-2 via a high frequency matching box 1115-2.

In FIG. 1, reference numeral 1116 denotes a gas supply pipe, 1117 denotes a first exhaust valve, 1118 denotes a second exhaust valve and 1127 denotes a gas supply valve.

The step 1128 indicates a section from the beginning to the end of the expansion of the inner diameter of the exhaust pipe 1122.

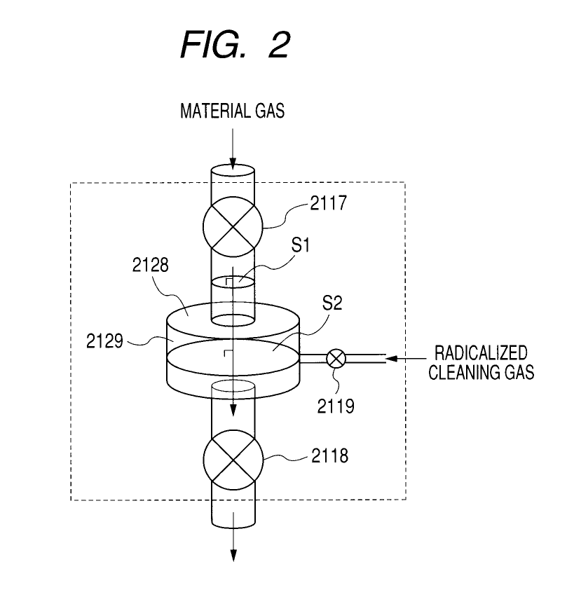

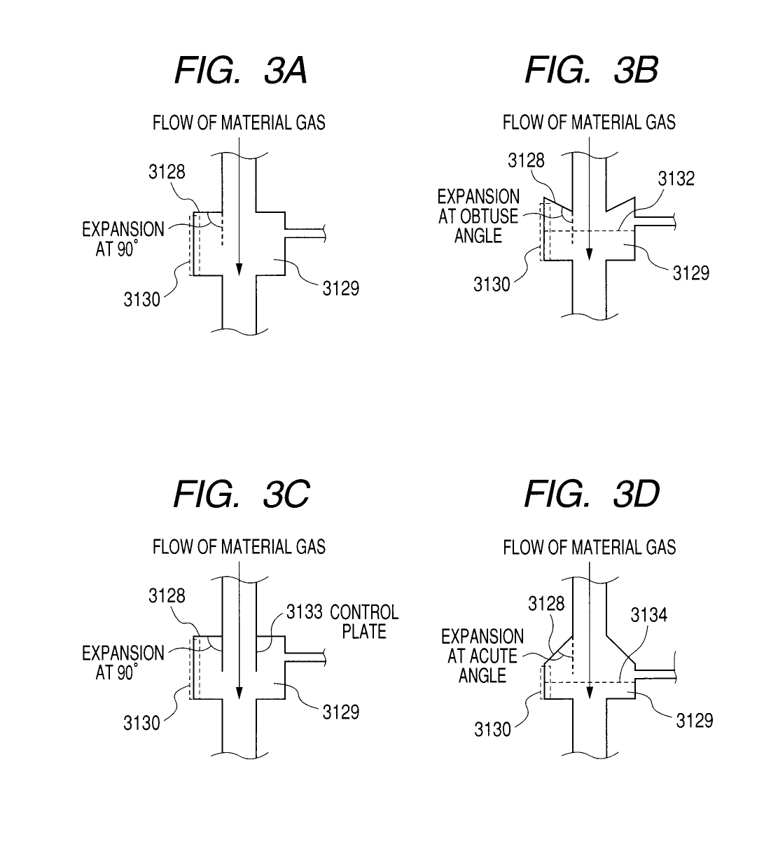

FIG. 2 and FIGS. 3A, 3B, 3C and 3D are schematic diagrams illustrating examples of the exhaust gas flow path.

Portions 1129, 2129 and 3129 whose cross section expands correspond to portions where an inner wall 3130 on the exhaust device side of the exhaust gas flow path (exhaust pipe) expands in the direction in which the material gas flows (indicated by arrows in FIGS. 3A, 3B, 3C and 3D).

In the example illustrated in FIG. 3A, the step 3128 expands at right angles (90 degrees) with respect to the direction in which the material gas flows. In the example illustrated in FIG. 3B, the step 3128 expands at an obtuse angle with respect to the direction in which the material gas flows. In the example illustrated in FIG. 3D, the step 3128 expands at an acute angle with respect to the direction in which the material gas flows. Furthermore, in the example illustrated in FIG. 3B, the obtuse angle means an angle greater than 90 degrees and smaller than 180 degrees. On the other hand, in the example in FIG. 3D, the acute angle means an angle greater than 30 degrees and smaller than 90 degrees.

Furthermore, as illustrated in FIG. 3C, the inner wall of the exhaust gas flow path (exhaust pipe) may expand in a rectangular shape as illustrated in FIG. 3A and a control plate 3133 may also be provided.

According to the present invention, as illustrated in FIGS. 3A, 3B and 3C, the inner wall (inner wall on the exhaust device side) 3130 of the exhaust gas flow path (exhaust pipe) can expand at 90 degrees or more in the direction in which the material gas flows compared to the case with the acute angle (less than 90 degrees) in FIG. 3D from the standpoint of reducing back diffusion.

The “cross section” of the exhaust gas flow path (exhaust pipe) of the present invention refers to, for example, the area of a plane perpendicular to the direction in which the material gas flows as illustrated by S1 and S2 in FIG. 2.

Here, the cross section (cross section on the exhaust device side) S2 of the portion 1129 whose cross section expands is the area of a vertical plane of the region into which the cleaning gas is directly introduced.

Furthermore, the cross section S2 can be equal to or greater than 3 times and equal to or less than 10 times the cross section (cross section on the reaction container side) S1 of the exhaust gas flow path (exhaust pipe) immediately before the expansion from the standpoint of reducing back diffusion and improving the cleaning efficiency. When the cross section S2 is smaller than 3 times the S1, the effect of suppressing back diffusion of the cleaning gas toward the reaction container side may decrease. Furthermore, when the cross section S2 is greater than 10 times the S1, the effect of suppressing back diffusion may be achieved, but the effect of improving the cleaning efficiency may decrease and the cleaning speed may decrease slightly. Furthermore, when the cross section S2 increases, the diameter of the pipe also increases accordingly, which leads to a cost increase or a reduction in the degree of freedom in a design of the apparatus.

Reference numeral 2117 in FIG. 2 denotes the first exhaust valve, 2118 denotes the second exhaust valve, 2119 denotes the gas supply valve and 2128 denotes the step.

Furthermore, the effect of suppressing the back diffusion of the cleaning gas toward the reaction container side is considered attributable to an increase in the number of times the cleaning gas flowing into the region closer to the exhaust device 1103 side than the step 1128 of the exhaust gas flow path 1102 collides with the inner wall of the step 1128 at the time of diffusion in the region.

Furthermore, assuming that the distance from the reaction container 1101 to the step 1128 is L1 and the distance from the step 1128 to the exhaust device 1103 is L2, the position where the step 1128 in the exhaust gas flow path 1102 is provided can be within a range in which L2/L1 is equal to or greater than 1 and equal to or less than 2. When the L2/L1 is equal to or greater than 1 and equal to or less than 2, it is possible to achieve both an improvement in the efficiency of processing of removing a by-product accumulated in the exhaust gas flow path or the exhaust device and suppression of back diffusion of the cleaning gas toward the reaction container 1101 side.

An example of a procedure of a deposition film forming method (vacuum deposition method) of the present invention using the deposition film forming apparatus in FIG. 1 will be described.

The cylindrical substrate 1112 is placed in the reaction container 1101 and the gas inside the reaction container 1101 is exhausted using the exhaust device 1103. Next, the heating heater 1113 controls the temperature of the cylindrical substrate 1112 to a desired temperature from 20° C. to 500° C.

Next, a material gas is introduced by the gas lead-in pipe 1114 into the reaction container 1101 via a gas supply valve 1132 at a predetermined flow rate. Next, when the inner pressure of the reaction container 1101 has been stabilized, the high frequency power supply 1120 is set to desired power and high frequency power (RF high frequency power) is supplied to the high frequency electrode 1111 via the high frequency matching box 1115 to generate high frequency glow discharge. With the discharge energy, the material gas introduced into the reaction container 1101 is decomposed and a desired deposition film is formed on the cylindrical substrate 1112.

Furthermore, at the same time as the above described material gas is introduced into the reaction container 1101 or while a deposition film is being formed, a cleaning gas radicalized by the cleaning gas flow device (plasma generation unit) 1124 is introduced into the region closer to the exhaust device 1103 side than the step 1128 of the exhaust gas flow path 1102 via the gas supply valve 1119. This suppresses the amount of by-product generated in the exhaust pipe 1122 or the exhaust device 1103 downstream of the step 1128. Furthermore, even when a deposition film is formed for a long time, the amount of by-product accumulated in the exhaust pipe 1122 is suppressed and the influences of a pressure variation and a pressure rise due to the clogging of the exhaust gas flow path 1102 (exhaust pipe 1122) are reduced.

Examples of the material gas include silane species such as silane (SiH₄) and disilane (Si₂H₆).

Examples of the cleaning gas include chlorine trifluoride (ClF₃), carbon tetrafluoride (CF₄), a mixed gas of carbon tetrafluoride (CF₄) and oxygen (O₂), nitrogen trifluoride (NF₃) and hexafluoroethane (C₂F₆). When silane species is used as the material gas from among these gases, chlorine trifluoride is preferable because chlorine trifluoride has excellent reactivity with polysilane, which is a by-product, and the cleaning efficiency improves a great deal. Furthermore, a mixed gas of chlorine trifluoride and diluent gas can be used because such a mixed gas improves controllability. An inert gas can be used as the diluent gas and any one of argon, nitrogen and helium or a mixed gas containing any one of argon, nitrogen and helium can further be used. Furthermore, a hydrogen gas can also be used as the diluent gas.

The present invention can also use a radicalized cleaning gas as the cleaning gas. Radicalizing a cleaning gas means decomposing the cleaning gas through an impact by electrons in plasma and generating active species having excellent chemical reactivity with the above described by-product to be cleaned. Furthermore, examples of the method of radicalizing the cleaning gas include decomposition through glow discharge, optical energy and thermal energy. Any method can be adopted if active species can be generated, but glow discharge is preferable from the standpoint of gas decomposition performance. To produce glow discharge, for example, DC power, RF (13.56 MHz) high frequency power and microwave power can be applied. For example, RF high frequency power is applied to a parallel plate electrode in a cylindrical plasma generating container via an insulator. As a result, glow discharge is generated in the plasma generating container, plasma is generated, the cleaning gas is decomposed and active species (radicalized cleaning gas) is generated.

After forming a deposition film, the present invention drastically shortens the processing time even in a step of processing of removing the by-product in the deposition film forming apparatus.

The deposition film forming method of the present invention is effective when a non single crystal deposition film including silicon atoms is formed using a material gas for supplying Si (silicon) such as silane species as a principal ingredient of the material gas. Application of the present invention to a method of forming a deposition film on the substrate and manufacturing an electrophotographic photosensitive member is especially effective.

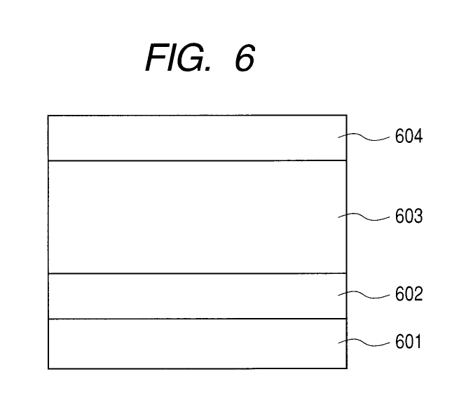

The deposition film forming method of the present invention is applicable to the formation of an amorphous silicon-based (a-Si-based) deposition film such as amorphous silicon deposition film (a-Si film) and amorphous silicon carbide deposition film (a-SiC film) as an example. For example, an a-Si-based electrophotographic photosensitive member (amorphous silicon photosensitive member) illustrated in FIG. 6 can be manufactured. FIG. 6 illustrates a configuration provided with an a-Si-based lower blocking layer 602, a photoconductive layer 603 and a surface layer 604 in that order on a substrate 601. The photoconductive layer 603 is made up of an a-Si film including hydrogen atoms or halogen atoms as components and has photoconductivity. Furthermore, the surface layer 604 is an a-Si film or a-SiC film.

Hereinafter, Examples of the present invention will be described but the present invention is not limited to these Examples.

### Example 1

An a-Si-based electrophotographic photosensitive member in the layer configuration illustrated in FIG. 6 was manufactured on an aluminum substrate (conductive substrate) worked into a mirror surface of 358 mm in length, 80 mm in outside diameter and 3 mm in thickness using the deposition film forming apparatus in FIG. 1 under a condition illustrated in Table 1.

In the formation of a deposition film according to the present Example, immediately after introducing a material gas into a reaction container, a radicalized cleaning gas was made to flow into a region closer to the exhaust device 1103 side than the step 1128 of the exhaust gas flow path 1102 under a condition illustrated in Table 2.

The step (inner wall of the exhaust gas flow path (exhaust pipe)) of the exhaust gas flow path expands in a shape at right angles with respect to the flow direction of the material gas as illustrated in FIG. 3A.

Here, the cross section (cross section on the exhaust device 1103 side) S2 of the region 1129 (3129) where the cross section of the exhaust gas flow path (exhaust pipe) expands with the step 1128 (3128) is 6 times the cross section (cross section on the reaction container 1101 side) S1 of the exhaust gas flow path (exhaust pipe) immediately before the expansion.

Furthermore, the cleaning gas was radicalized using a microwave plasma generation unit. A mixed gas of chlorine trifluoride (50%) and argon (50%) as a diluent gas was radicalized and used as the cleaning gas.

The by-product (polysilane) in the reaction container and in the exhaust gas flow path was then removed under a condition illustrated in Table 3. The procedure for removing the by-product was performed as follows.

After manufacturing the electrophotographic photosensitive member, the electrophotographic photosensitive member is taken out, a dummy cylinder for removing the by-product is placed instead and the gas inside the reaction container is exhausted. After sufficiently exhausting the gas inside the reaction container, the cleaning gas was introduced into the reaction container, the pressure was adjusted, RF high frequency power was applied to the discharge electrode and plasma was generated.

TABLE 1

| | Lower | Photocon- | Surface |
|---|---|---|---|
| | blocking | ductive | protective |
| | layer | layer | layer |
| SiH₄ (ml/min (normal)) | 100 | 500 | 100 |
| H₂ (ml/min (normal)) | 490 | 480 | 0 |
| B₂H₆ (ppm . . . vs. SiH₄) | 2000 | 0.5 | 0 |
| NO (ml/min (normal)) | 10 | 0 | 0 |
| CH₄ (ml/min (normal)) | 0 | 0 | 450 |
| RF high frequency power (W) | 100 | 500 | 65 |
| Inner pressure (Pa) | 67 | 67 | 67 |
| Substrate temperature (° C.) | 260 | 260 | 200 |
| Film thickness (μm) | 5 | 40 | 0.5 |

TABLE 2

| Item | Condition |
|---|---|
| Cleaning gas species | ClF₃(50%)/Ar(50%) mixed gas |
| Flow rate (ml/min (normal)) | 100 |
| Plasma generating unit | Microwave |
| RF high frequency power (W) | 300 |

TABLE 3

| Item | Condition |
|---|---|
| Gas species | ClF₃(35%)/Ar(65%) mixed gas |
| Flow rate (ml/min (normal)) | 800 |
| RF high frequency power (W) | 1000 |
| Inner pressure (Pa) | 67 |

### Comparative Example 1

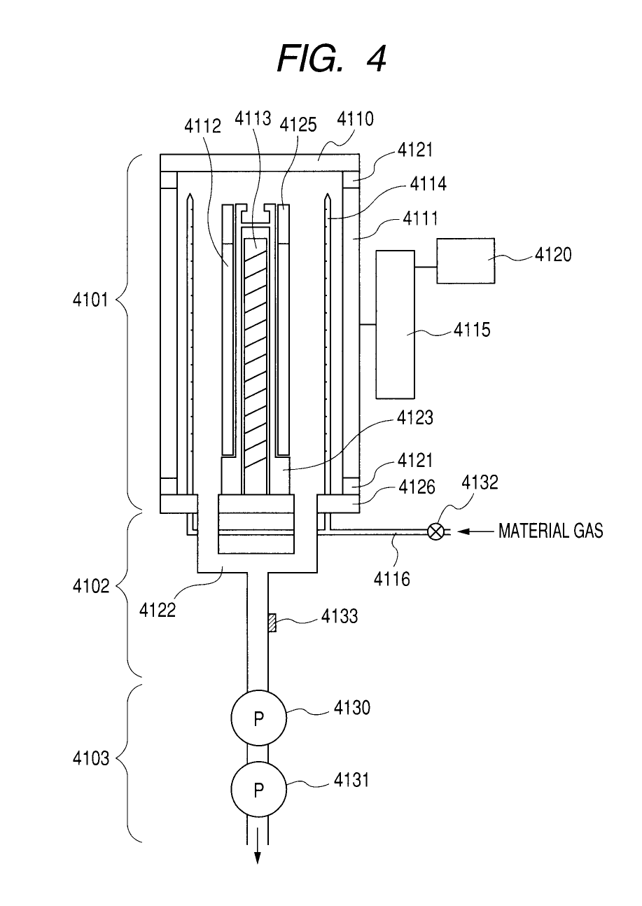

An a-Si-based electrophotographic photosensitive member in the layer configuration illustrated in FIG. 6 was manufactured on an aluminum substrate (conductive substrate) worked into a mirror surface of 358 mm in length, 80 mm in outside diameter and 3 mm in thickness using the conventional deposition film forming apparatus illustrated in FIG. 4 under the condition illustrated in Table 1. Furthermore, as in the case of Example 1, after forming a deposition film, the by-product (polysilane) in the reaction container and in the exhaust gas flow path was removed under the condition illustrated in Table 3.

The deposition film forming apparatus in FIG. 4 has no part whose cross section expands with a step in the exhaust gas flow path and no cleaning gas was made to flow into the exhaust gas flow path in the formation of a deposition film.

In FIG. 4, reference numeral 4101 denotes a reaction container, 4102 denotes an exhaust gas flow path and 4103 denotes an exhaust device. Furthermore, 4110 denotes a top cover, 4111 denotes a high frequency electrode, 4112 denotes a cylindrical substrate, 4113 denotes a heater for heating a substrate, 4114 denotes a gas lead-in pipe, 4115 denotes a high frequency matching box and 4116 denotes a gas supply pipe. Furthermore, 4120 denotes a high frequency power supply, 4121 denotes an insulating member, 4122 denotes an exhaust pipe, 4123 denotes a substrate holder, 4125 denotes a cap holder and 4126 denotes a bottom plate. Furthermore, 4130 denotes a mechanical booster pump, 4131 denotes an oil rotation pump, 4132 denotes a gas supply valve and 4133 denotes an observation hole.

### Comparative Example 2

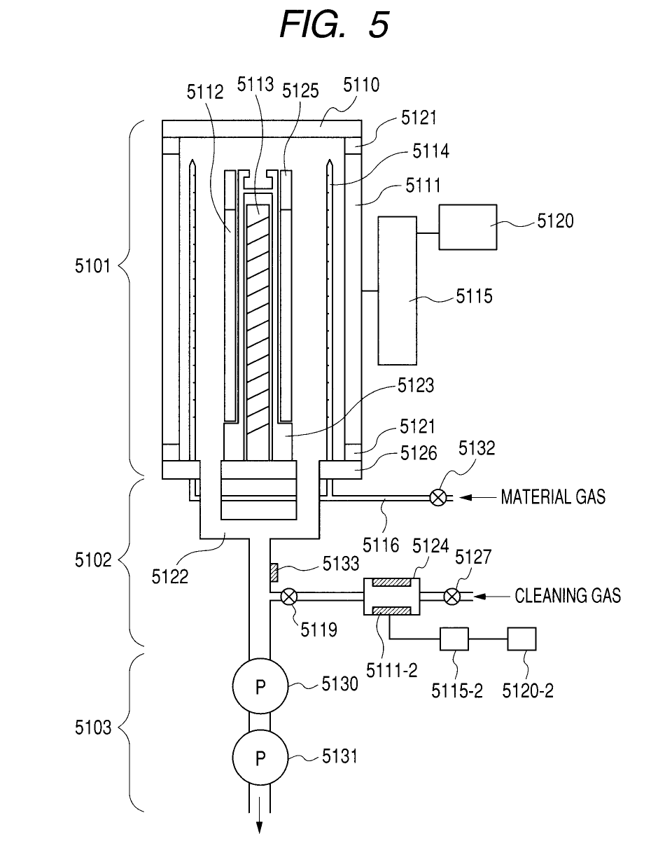

An a-Si-based electrophotographic photosensitive member in the layer configuration illustrated in FIG. 6 was manufactured on an aluminum substrate (conductive substrate) worked into a mirror surface of 358 mm in length, 80 mm in outside diameter and 3 mm in thickness using the conventional deposition film forming apparatus illustrated in FIG. 5 under the condition illustrated in Table 1. Furthermore, as in the case of Example 1, after forming a deposition film, the by-product (polysilane) in the reaction container and in the exhaust gas flow path was removed under the condition illustrated in Table 3.

Although the deposition film forming apparatus in FIG. 5 has no part whose cross section expands with a step in the exhaust gas flow path, a radicalized cleaning gas was made to flow into the exhaust gas flow path under the condition illustrated in Table 2 immediately after introducing the material gas into the reaction container in the formation of a deposition film.

Here, the cleaning gas was radicalized using a microwave plasma generation unit as in the case of Example 1. Furthermore, a mixed gas of chlorine trifluoride (50%) and argon (50%) as a diluent gas was radicalized and used as the cleaning gas as in the case of Example 1.

In FIG. 5, reference numeral 5101 denotes a reaction container, 5102 denotes an exhaust gas flow path and 5103 denotes an exhaust device. Furthermore, 5110 denotes a top cover, 5111 denotes a high frequency electrode, 5112 denotes a cylindrical substrate, 5113 denotes a heater for heating a substrate, 5114 denotes a gas lead-in pipe, 5115 denotes a high frequency matching box and 5116 denotes a gas supply pipe. Furthermore, 5120 denotes a high frequency power supply, 5121 denotes an insulating member, 5122 denotes an exhaust pipe, 5123 denotes a substrate holder, 5124 denotes a cleaning gas flow device, 5125 denotes a cap holder and 5126 denotes a bottom plate. Furthermore, 5130 denotes a mechanical booster pump, 5131 denotes an oil rotation pump, 5132 denotes a gas supply valve and 5133 denotes an observation hole. Furthermore, 5111-2 denotes a high frequency electrode, 5115-2 denotes a high frequency matching box and 5120-2 denotes a high frequency power supply.

### Example 2

In the same way as in Example 1 with an exception that the exhaust gas flow path was made to expand in the shape illustrated in FIG. 3B, an a-Si-based electrophotographic photosensitive member in the layer configuration illustrated in FIG. 6 was manufactured on an aluminum substrate (conductive substrate) worked into a mirror surface of 358 mm in length, 80 mm in outside diameter and 3 mm in thickness using the deposition film forming apparatus illustrated in FIG. 1 under the condition illustrated in Table 1.

Furthermore, as in the case of Example 1, in the formation of a deposition film, immediately after introducing the material gas into the reaction container, a radicalized cleaning gas was made to flow into a region closer to the exhaust device side than the step of the exhaust gas flow path under the condition illustrated in Table 2.

According to the present Example, the cross section S2 of a portion 1129 (3129) where the cross section of the exhaust gas flow path (exhaust pipe) expands with the step 1128 (3128) is made to be 2 times to 11 times (to be more specific, 4 different times; 2 times, 3 times, 10 times and 11 times) the cross section (cross section on the reaction container 1101 side) S1 of the exhaust gas flow path (exhaust pipe) immediately before the expansion. In the present Example, suppose the cross section S2 is the cross section at the position 3132 illustrated in FIG. 3B.

Furthermore, the exhaust gas flow path expands in the shape illustrated in FIG. 3B, and to be more specific, such a shape that the step (inner wall of the exhaust gas flow path (exhaust pipe)) expands at an obtuse angle (135 degrees) with respect to the direction in which the material gas flows.

### Example 3

In the same way as in Example 1 with an exception that the exhaust gas flow path was made to expand in the shape illustrated in FIG. 3C, an a-Si-based electrophotographic photosensitive member in the layer configuration illustrated in FIG. 6 was manufactured on an aluminum substrate (conductive substrate) worked into a mirror surface of 358 mm in length, 80 mm in outside diameter and 3 mm in thickness using the deposition film forming apparatus illustrated in FIG. 1 under the condition illustrated in Table 1.

Furthermore, as in the case of Example 1, in the formation of a deposition film, immediately after introducing the material gas into the reaction container, a radicalized cleaning gas was made to flow into a region closer to the exhaust device side than the step of the exhaust gas flow path under the condition illustrated in Table 4.

Here, the cross section (cross section on the exhaust device 1103 side) S2 of the region 1129 (3129) where the cross section of the exhaust gas flow path (exhaust pipe) expands with the step 1128 (3128) is 6 times the cross section (cross section on the reaction container 1101 side) S1 of the exhaust gas flow path (exhaust pipe) immediately before the expansion.

Furthermore, the exhaust gas flow path expands in the shape illustrated in FIG. 3C, and to be more specific, such a shape that the step (inner wall of the exhaust gas flow path) expands at right angles with respect to the direction in which the material gas flows, and the control plate 3133 is further provided.

In the present Example, carbon tetrafluoride was radicalized and used as a cleaning gas.

TABLE 4

| Item | Condition |
|---|---|
| Cleaning gas species | CF₄ |
| Flow rate (ml/min (normal)) | 100 |
| Plasma generating unit | RF |
| RF high frequency power (W) | 300 |

### Example 4

In the same way as in Example 1 with an exception that the exhaust gas flow path is made to expand in the shape illustrated in FIG. 3D, an a-Si-based electrophotographic photosensitive member in the layer configuration illustrated in FIG. 6 was manufactured on an aluminum substrate (conductive substrate) worked into a mirror surface of 358 mm in length, 80 mm in outside diameter and 3 mm in thickness using the deposition film forming apparatus illustrated in FIG. 1 under the condition illustrated in Table 1.

Furthermore, as in the case of Example 1, in the formation of a deposition film, immediately after introducing the material gas into the reaction container, a radicalized cleaning gas was made to flow into a region closer to the exhaust device side than the step of the exhaust gas flow path under the condition illustrated in Table 2.

Here, the cross section (cross section on the exhaust device 1103 side) S2 of the region 1129 (3129) where the cross section of the exhaust gas flow path (exhaust pipe) expands with the step 1128 (3128) is 6 times the cross section (cross section on the reaction container 1101 side) S1 of the exhaust gas flow path (exhaust pipe) immediately before the expansion. According to the present Example, suppose the cross section S2 is the cross section at the position 3134 illustrated in FIG. 3D.

Furthermore, the exhaust gas flow path expands in the shape illustrated in FIG. 3D, and to be more specific, such a shape that the step (inner wall of the exhaust gas flow path (exhaust pipe)) expands at an acute angle (60 degrees) with respect to the direction in which the material gas flows.

A more detailed evaluation method will be described below.

“Analysis of Amount of Impurity”

The content of fluorine of the electrophotographic photosensitive member manufactured in Examples 1 to 3 and comparative examples 1 and 2 was measured using an SIMS (Secondary Ion-microprobe Mass Spectrometer) analyzer (IMS-4F manufactured by CAMECA). This fluorine is considered to mainly derive from chlorine trifluoride or carbon tetrafluoride in the cleaning gas. As the content of fluorine decreases, the amount of the component of the cleaning gas mixed in the formed deposition film is considered to be smaller. More specific measurement was performed at a position of 5 μm in depth from the surface of the electrophotographic photosensitive member under the condition of primary ion species: Cs⁺, secondary ion species: negative, primary ion energy: 14.5 keV, amount of primary ion current: 8 nA, analysis region: diameter 30 μm.

The evaluation value is a relative value when the content of fluorine in the deposition film in comparative example 2 is assumed to be 1.

“Evaluation of Electric Characteristic of Electrophotographic Photosensitive Member”

Next, the electrophotographic photosensitive member manufactured in Examples 1 to 3 and comparative examples 1 and 2 was set in an electrophotographic apparatus (iR5065 manufactured by Canon Inc. remodeled for experiment) and the electrophotographic characteristic of the electrophotographic photosensitive member was evaluated using the following method.

“Residual Potential Measurement Method”

After irradiating exposure light (LED having a wavelength of 670 nm) onto the electrophotographic photosensitive member at an intensity of 2.4 μJ/cm², the electrophotographic photosensitive member is charged so that a dark area surface potential at the development position of the electrophotographic photosensitive member becomes 400 (V). The electrophotographic photosensitive member is then irradiated with image exposure light (semiconductor laser having an oscillating wavelength of 658 nm) at an intensity of 0.9 μJ/cm², a light area surface potential of the electrophotographic photosensitive member at the development position is measured using a surface potentiometer and the measured value in this case is assumed to be a residual potential. The smaller the numerical value, the better is the residual potential and the more excellent is electrophotographic characteristic.

The measured values of the electrophotographic photosensitive member manufactured in Examples and comparative examples were compared with the measured values of the electrophotographic photosensitive member manufactured in comparative example 2 and thereby classified into the following ranks.

A; residual potential reduced by 10% or more compared to comparative example 2

B; residual potential reduced by 5% or more and less than 10% compared to comparative example 2

C; residual potential at least equivalent or reduced by less than 5% compared to comparative example 2

D; residual potential increased compared to comparative example 2

“Sensitivity Measurement Method”

The electrophotographic photosensitive member is charged so that the dark area surface potential at the development position of the electrophotographic photosensitive member becomes 400 (V). The electrophotographic photosensitive member is then irradiated with image exposure light (semiconductor laser having an oscillating wavelength of 658 nm) so that the light area surface potential at the development position of the electrophotographic photosensitive member becomes 50 (V) (the light quantity of the image exposure light is adjusted so that the light area surface potential at the development position of the electrophotographic photosensitive member becomes 50 (V)). Sensitivity is evaluated according to the light quantity value in this case. The smaller the numerical value, the better is the sensitivity and the more excellent is the electrophotographic characteristic.

The measured values of the electrophotographic photosensitive member manufactured in Examples and comparative examples are compared with the measured values of the electrophotographic photosensitive member manufactured in comparative example 2 and classified into the following ranks.

A; sensitivity improved by 10% or more compared to comparative example 2

B; sensitivity improved by 5% or more and less than 10% compared to comparative example 2

C; sensitivity at least equivalent or improved by less than 5% compared to comparative example 2

D; sensitivity deteriorated compared to comparative example 2

“Optical Memory Measurement Method”

As in the case of the above described sensitivity measurement method, using laser light of a semiconductor laser having an oscillating wavelength of 658 nm as image exposure light, a difference (potential difference) between the surface potential at the development position without exposure and the surface potential at a time of recharging after exposure is measured. Optical memory is evaluated using the potential difference value in this case. The smaller the numerical value, the better is the optical memory and the more excellent is the electrophotographic characteristic.

The measured values of the electrophotographic photosensitive member manufactured in Examples and comparative examples are compared with the measured values of the electrophotographic photosensitive member manufactured in comparative example 2 and classified into the following ranks.

A; optical memory improved by 20% or more compared to comparative example 2

B; optical memory improved by 10% or more and less than 20% compared to comparative example 2

C; optical memory at least equivalent or improved by less than 10% compared to comparative example 2

D; optical memory deteriorated compared to comparative example 2

“Cleaning Speed after Forming Deposition Film”

With regard to Examples 1 to 3 and comparative examples 1 and 2, the conditions of a by-product (polysilane) during processing of removing the by-product (polysilane) in the reaction container and in the exhaust gas flow path and that in the exhaust gas flow path 2 hours later were checked and the by-product (polysilane) removing processing speed was determined as follows. The condition of the by-product (polysilane) was checked by providing the observation hole 1133 in the exhaust gas flow path, images were taken using a CCD camera and the amount of the by-product (polysilane) in 5 cm² of the image taken was evaluated.

A no by-product (polysilane) remains.

B a small amount of by-product (polysilane) remains.

C a large amount of by-product (polysilane) remains.

“Comprehensive Evaluation”

Based on the evaluation result, the following comprehensive determination was made.

A all results correspond to A (excellent).

B no result corresponds to C or D, but at least 1 corresponds to B (good).

C no result corresponds to D, but at least 1 corresponds to C.

D At least 1 corresponds to D.

In summary, the results obtained are shown in Table 5.

From the fluorine content in Examples 1 to 3 and comparative example 2, it is possible to suppress back diffusion of the cleaning gas toward the reaction container side even if a radicalized cleaning gas is made to directly flow into the region closer to the exhaust device side than the step of the exhaust gas flow path. As a result, the impurity component (cleaning gas component) mixed into the formed deposition film was reduced down to a level without problems. Furthermore, from the evaluation results of the residual potential, sensitivity and optical memory, an electrophotographic photosensitive member of good electrophotographic characteristics could be obtained.

Based on the cleaning speed of the exhaust gas flow path in Examples 1 to 3 and comparative example 1, it has been proved that the amount of by-product (polysilane) accumulated in the exhaust gas flow path during the formation of the deposition film in Examples 1 to 3 decreases, and therefore the by-product (polysilane) in the reaction container and in the exhaust gas flow path can be removed in a shorter time after manufacturing the electrophotographic photosensitive member.

According to Example 2, the cross section was tripled or more, the fluorine content was thereby reduced and excellent electrophotographic characteristic could be obtained. Furthermore, the cross section was set to within a range of 10 times or less, and the cleaning speed of the exhaust gas flow path could thereby be improved. It is thereby proven that both an excellent electrophotographic characteristic and an improvement of the cleaning speed can be achieved when the cross section is within a range of 3 times or more and less than 10 times.

According to Example 1 and Example 3, it has been proven that the use of a gas containing chlorine trifluoride as the cleaning gas enables the cleaning speed to be improved.

According to Example 1 and Example 4, it has been proven that by forming the step in the rectangular shape illustrated in FIG. 3A, the fluorine content is reduced compared to the case with the acute angle shape illustrated in FIG. 3D and an excellent electrophotographic characteristic can be obtained.

TABLE 5

| | | | | | | | | Comparative | Comparative |
|---|---|---|---|---|---|---|---|---|---|
| | Example 1 | Example 2 | | | | Example 3 | Example 4 | example 1 | example 2 |
| Cross section | 6 times | 2 times | 3 times | 10 times | 11 times | 6 times | 6 times | No step | No step |
| of exhaust pipe | | | | | | | | | |
| Radical | Plasma | Plasma | Plasma | Plasma | Plasma | Plasma | Plasma | None | Plasma |
| generating unit | | | | | | | | | |
| Cleaning gas | ClF₃/Ar | ClF₃/Ar | ClF₃/Ar | ClF₃/Ar | ClF₃/Ar | CF₄ | ClF₃/Ar | ClF₃/Ar | ClF₃/Ar |
| Step shape | FIG. 3A | FIG. 3B | FIG. 3B | FIG. 3B | FIG. 3B | FIG. 3C Right | FIG. 3D Acute | No step | No step |
| | Right | Obtuse | Obtuse | Obtuse | Obtuse | angle + | angle | | |
| | angle | angle | angle | angle | angle | control plate | | | |
| Fluorine | 3.0 × 10⁻² | 9.0 × 10⁻² | 5.0 × 10⁻² | 1.5 × 10⁻² | 1.3 × 10⁻² | 4.0 × 10⁻² | 9.5 × 10⁻² | 1.0 × 10⁻² | 1 |
| content in | | | | | | | | | |
| deposition | | | | | | | | | |
| film | | | | | | | | | |
| (relative value) | | | | | | | | | |
| Residual | A | B | A | A | A | A | B | A | C |
| potential | | | | | | | | | |
| Sensitivity | A | B | A | A | A | A | B | A | C |
| Optical | A | B | A | A | A | A | B | A | C |
| memory | | | | | | | | | |
| Cleaning speed | A | A | A | A | B | B | A | C | A |
| of exhaust pipe | | | | | | | | | |
| Comprehensive | A | B | A | A | B | B | B | C | C |
| evaluation | | | | | | | | | |

While the present invention has been described with reference to Examples, it is to be understood that the invention is not limited to the disclosed Examples. The scope of the following claims is to be accorded the broadest interpretation so as to encompass all such modifications and equivalent structures and functions.

This application claims the benefit of Japanese Patent Application No. 2008-324205, filed on Dec. 19, 2008, which is hereby incorporated by reference herein in its entirety.

What is claimed is:

1. A deposition film forming apparatus comprising:
a reaction container that can be vacuum-sealed for decomposing a material gas and causing the material gas to be vapor-deposited on a substrate to form a deposition film;
an exhaust device for exhausting a gas from the reaction container; and
an exhaust gas flow path for communicating between the reaction container and the exhaust device and causing the material gas to flow from the reaction container to the exhaust device,
wherein the exhaust gas flow path comprises a portion whose cross section expands with a step with respect to a direction in which the material gas flows, and
the deposition film forming apparatus further comprises a cleaning gas flow device for causing the cleaning gas to directly flow into a region closer to the exhaust device side than the step of the exhaust gas flow path.

2. The deposition film forming apparatus according to claim 1, wherein a cross section closer to the exhaust device side than the step of the exhaust gas flow path is 3 times or more and 10 times or less than the cross section closer to the reaction container side than the step of the exhaust gas flow path.

3. The deposition film forming apparatus according to claim 1, wherein an inner wall of the exhaust gas flow path expands at the step by 90 degrees or more with respect to a direction in which the material gas flows.

4. The deposition film forming apparatus according to claim 1, wherein the material gas is a gas containing silane species and the deposition film is a non single crystal deposition film that includes silicon atoms as a principal ingredient.

5. The deposition film forming apparatus according to claim 4, wherein the cleaning gas is a gas containing chlorine trifluoride.

6. The deposition film forming apparatus according to claim 1, wherein the cleaning gas is a radicalized cleaning gas.

7. A method of forming a deposition film on a substrate using the deposition film forming apparatus according to claim 1:
decomposing a material gas in the reaction container;
causing the material gas to be vapor-deposited on a substrate to form a deposition film; and
causing a cleaning gas to directly flow into a region closer to the exhaust device side than the step of the exhaust gas flow path.

8. The deposition film forming method according to claim 7, wherein the material gas is a gas containing silane species and the deposition film is a non single crystal deposition film containing silicon atoms as a principal ingredient.

9. The deposition film forming method according to claim 8, wherein the cleaning gas is a gas containing chlorine trifluoride.

10. The deposition film forming method according to claim 7, wherein the cleaning gas is a radicalized cleaning gas.

11. An electrophotographic photosensitive member manufacturing method for forming a deposition film on a substrate and manufacturing an electrophotographic photosensitive member, the method using the deposition film forming method according to claim 7 to form the deposition film on the substrate.
